(19) United States
(12) Patent Application Publication
(10) Pub. No.: US 2009/0108757 A1
(43) Pub. Date: Apr. 30, 2009

(54) ONE-PIECE ORGANIC LIGHT EMITTING DIODE DISPLAY DEVICE WITH AN ENERGY-RECYCLING FEATURE AND HIGH CONTRAST

(75) Inventors: Si-Chen Lee, Taipei (TW); Chung-Chih Wu, Taipei (TW); Chih-Jen Yang, Taipei (TW); Ting-Yi Cho, Taipei (TW); Che-Yu Yang, Taipei (TW); Yen-Yu Chen, Taipei (TW); Chun-Liang Lin, Taipei (TW)

Correspondence Address: RABIN & Berdo, PC, 1101 14TH STREET, NW, SUITE 500, WASHINGTON, DC, 20005, US

(73) Assignee: National Taiwan University, Taipei (TW)

(21) Appl. No.: 12/254,999

(22) Filed: Oct. 21, 2008

(30) Foreign Application Priority Data
Oct. 22, 2007 (TW) 096139547

(51) Int. Cl. H01L 51/52

(52) U.S. Cl. 315/51

(57) ABSTRACT

This invention is an electricity generating organic light-emitting display device (OLED) consisting of vertically stacked layers including an organic light emitting device (OLED), an insulation layer, a solar cell and thin film transistors. The device can reduce the reflection of ambient light, improve the contrast of the signal, and enhance sun-light readability by allowing the ambient light to be absorbed by the solar cells. Furthermore, additional power will be generated by the solar cell through absorption of ambient light and backward emission of OLEDs. The device, without using the polarizer, can exhibit low reflectance characteristics over the visible region and high display contrast.

### FIELD OF THE INVENTION

The invention relates to a one-piece organic light emitting diode (OLED) display, and more particularly, to an OLED display with an energy-recycling feature and high contrast.

### BACKGROUND OF THE RELATED ART

Because of recent developments in solid-state chemistry and pellicle semiconductor technology, flat panel displays using electroluminescent (EL) material have become easier to manufacture. EL material is available in two types, organic and inorganic. In the past, most research focused on inorganic EL, which resulted in the related technology maturing quickly, and products based on inorganic EL being more popular. The industrial application value of organic EL has become more important because the limitations and drawbacks of organic EL such as limited luminous efficiency and a relatively short operating life-cycle have been overcome.

With reference to FIG. 1, a conventional organic light emitting diode (OLED) in accordance with the prior art comprises a substrate (11), a first electrode layer (12), an organic material layer (13), a second electrode layer (14) and an optional polarizer (15). The substrate (11) is glass. The first electrode layer (12) comprises a 120 nm indium tin oxide (ITO) layer and is an anode, and the second electrode layer (14) comprises 0.5 nm lithium fluoride (LiF) layer and 100 nm aluminum (Al) layer and is a cathode. The organic material layer (13) comprises a 30 nm layer of m-MTDATA (4,4′,4″-tris(3-methylphenylphenylamino) triphenylamine), a 60 nm Alq₃ layer (tris-(8-hydroxyquinolinol) aluminium), and a 20 nm layer 4,4′-bis[N(1-naphthyl)-N-phenyl-amino]biphenyl (α-NPD). The polarizer (15) is usually circular, is attached to the OLED (1) to increase the contrast of the OLED (1) and may be attached to the second electrode layer (14).

Conventionally, metal with high reflectivity has been used as a reflective electrode in EL devices to give better luminous efficiency. However, the readability of the display is reduced by using high-reflectivity electrode when ambient light is increased. Therefore, to keep enough contrast, the EL material must be driven to higher brightnesses to overcome the reduced clarity/readability of the display, which results in increased energy loss and shortens the products' life cycles, especially for portable devices. Therefore, in this invention, it is disclosed that a photovoltaic element can be mounted to the back (i.e. the non-display side) of a translucent organic LED, so that the photovoltaic element that can adsorb ambient light passing through the translucent EL device, decrease reflection of ambient light and convert ambient light to electricity for use in driving the EL device or other components in the system to increase system-level power efficiency.

Photovoltaic elements and EL elements are usually combined with displays of different devices, such as digital watches and electronic calculators, for generation of electricity. In such implementations, the photovoltaic elements are installed on a non-display surface or area of the display. In such implementations, on one hand, additional space is needed to install the photovoltaic element, as also shown in many recent patents. On the other hand, these conventional implementations provide no functions of reducing the reflection of ambient light or enhancing the display contrast/readability.

For example, U.S. Pat. No. 6,020,943 published on Feb. 1, 2000, entitled “Display device having a display plate with a plurality of openings formed therein, disposed above an EL light emitting member” discloses an electronic device and a display that is used for various types of electronic devices, e.g., digital watches, electronic pocket notebooks and the like. In the device, a solar cell having many light passing openings to allow light to pass is mounted between a liquid crystal display and a flat light emitting element mounted under the liquid crystal display member.

U.S. Pat. No. 6,323,923 published on Nov. 27, 2001, entitled “Reflective type LCD having a solar cell formed of same material and same surface as an active element” discloses a reflective type liquid crystal display and a solar cell. The reflective type liquid crystal display has a first transparent substrate, a second transparent substrate, and a light scattering liquid crystal layer and may have one or more color filters. The light scattering liquid crystal layer is mounted between the first and second transparent substrates and has a separate pixel area. The solar cell is mounted on the second transparent substrate and comprises an active element that drives the light scattering liquid crystal layer. The patent only applies to the liquid crystal display, even though the solar cell decreases reflectivity of the pixel area of the liquid crystal display, and color filters added for color panels weaken light for the solar cell.

U.S. Pat. No. 6,967,700 published on Nov. 22, 2005, entitled “Sequential full color display and photocell device” discloses a full color display and photocell device that comprise a fast response liquid crystal display, a transparent panel light and a photovoltaic cell and may include a controller The fast response liquid crystal display has a rate of at least 75 monochrome frames per second. The transparent panel light is mounted behind the fast response LCD that can emit a monochromatic light beam having a selected one of three colors. The photovoltaic cell is mounted behind the transparent panel light and converts light emanating from the transparent panel light into electricity. The controller synchronizes information coupled to the fast response LCD and causes the transparent panel light to emit a sequence of monochromatic light beams of three colors. However, the way to improve the contrast of the LCD is not addressed, and the intensity and contrast of the liquid crystal display device will be decreased.

Luxell Technologies Inc. in Canada owns several patents dealing with high contrast OLED's, including U.S. Pat. No. 6,411,019 published on Jun. 25, 2002, entitled “Organic electroluminescent device” and U.S. Pat. No. 6,551,651 published on Apr. 22, 2003, entitled “Method of fabricating an organic electroluminescent device.” Both patents focus on improvement of a bottom-emitting OLED having an anode and a cathode and disclose an optical interference member having a work function, made of organic material with a work function and mounted between the anode and the cathode of the OLED and the work function of the material of the optical interference member and organic material are designed to decrease the reflectivity and to increase the contrast of the OLED element.

US Patent Application No. 20040201985 published on Oct. 14, 2004, entitled “Automatic contrast compensation apparatus for an organic light-emitting diode display” discloses an automatic contrast compensation apparatus for an OLED display, which comprises a photo detector, an OLED driver, a safety clamping circuit and a solar cell. When ambient light's intensity increases, the photo detector sends a signal to the OLED driver to increase the brightness of the OLED display. The solar cell provides the extra power for the OLED driver to improve display performance of the OLED display in a power-saving manner. The safety clamping circuit prevents an over-current condition in the OLED driver from the solar cell.

US Patent Application No. 20050260777 published on Nov. 24, 2005, entitled “Organic luminous diode, method for the production thereof and uses thereof” discloses an organic light emitting diode (OLED), also referred to as a light emitting diode, and an energy carrier. The OLED comprises at least one substrate, one anode, one perforated transport layer, one emitter layer, one cathode and encapsulant. The energy carrier supplies voltage that causes the OLED to emit light, has been proposed to be integrated into the OLED and can be a battery or an energy converter. However, the OLED or the energy carrier are mounted on different substrates and are connected to each other mechanically that causes fabrication for different applications to be difficult.

US Patent Application No. 20060227531 published on Oct. 12, 2006, entitled “Electroluminescent displays” discloses an organic light emitting diode display, and the electroluminescent display comprises a substrate and organic light emitting diodes. Each organic light emitting diode has a substrate, an organic light emitting layer, a conductive layer and a photovoltaic cell. The organic light emitting layer is mounted on the substrate. The conductive layer is mounted on the organic light emitting layer and is a common electrode for the OLED. The photovoltaic cell is mounted on the organic light emitting diode, converts incident light into electricity and may be connected to the common electrode of the OLED.

Most of the foregoing patents focus on displays with solar cells mechanically mounted and research connecting the solar cell in the display element of only liquid crystal displays. The OLED display commonly uses a polarizer to improve contrast. The associated research does not address solar cells being used to improve contrast and provide electricity.

### SUMMARY OF THE INVENTION

The main objective of an OLED display in accordance with the present invention is to provide an organic light emitting diode (OLED) display device with an energy-recycling feature and high contrast.

The present invention relates to a one-piece organic light-emitting diode (OLED) display device with energy-recycling feature and high contrast. The OLED display device comprises a substrate, a photovoltaic element and a translucent OLED element being vertical stacking to the photovoltaic element. The organic light-emitting element comprises a lower electrode layer, an organic light-emitting material layer and an upper electrode layer mounted against each other to form the OLED display device. The OLED element is translucent. Ambient light passing through the translucent OLED element is adsorbed by the photovoltaic element. The photovoltaic element reduces ambient light reflected and converts the light into electricity.

Accordance with the present invention, the OLED display device is top-emitting that the photovoltaic element is mounted between the substrate and the OLED element or bottom emitting that the OLED display device is bottom-emitting and the OLED element is mounted between the substrate and the photovoltaic element.

### BRIEF DESCRIPTION OF THE DRAWINGS

Many of the attendant advantages and features of this invention will become more apparent by reference to the following detailed description, when taken in conjunction with the accompanying drawings.

FIG. 1 is a side view of a conventional OLED.

FIG. 2 is a side view of a first embodiment of an OLED in accordance with the present invention.

FIG. 3 is a side view of a second embodiment of an OLED in accordance with the present invention.

FIG. 4 is a side view of a third embodiment of an OLED in accordance with the present invention.

FIG. 5 is a graph of luminescence spectra of the OLED (B, C, D) in FIG. 4 viewed at 0°, 30° and 60° compared to a conventional OLED (A).

FIG. 6 is a graph of reflection spectra of the OLED in FIG. 4 (F) compared to a conventional OLED (E).

FIG. 7 is a graph of brightness and current density of a conventional OLED (G) the OLED (H) in FIG. 4.

FIG. 8(a1) is a graph of the response of the photovoltaic element in FIG. 4 under ambient light conditions including being in darkness (I) and controlled light (J) where brightness is AM1.5.

FIG. 8(a2) is a graph of the quantum efficiency of the photovoltaic element in FIG. 4.

FIG. 8(b) is a graph of the response of the OLED element in FIG. 4 when the photovoltaic element when (K) the OLED element is in the dark and is not lighted and (L) the OLED element is driven by 20 mA/cm² current and the brightness is 316 cd/m².

FIG. 9 is a side view of a forth embodiment of an OLED in accordance with the present invention.

FIG. 10 is a graph of reflection spectra of a conventional OLED (M) without a polarizer attached and the OLED (N) in FIG. 9.

FIG. 11 is a side view of a fifth embodiment of an OLED in accordance with the present invention.

FIG. 12 is, a graph of reflection rate of the OLED in FIG. 11.

FIG. 13 is a side view of the sixth embodiment of an OLED in accordance with the present invention.

FIG. 14 is a graph of reflection rate of the OLED in FIG. 13.

FIG. 15 is a side view of a seventh embodiment of an OLED in accordance with the present invention.

FIG. 16 is a graph electrical properties and luminescence spectrum of the OLED in FIG. 15.

FIG. 17 is a graph of quantum efficiency of the OLED in FIG. 15.

FIG. 18 is a graph of energy recovery of the OLED in FIG. 15.

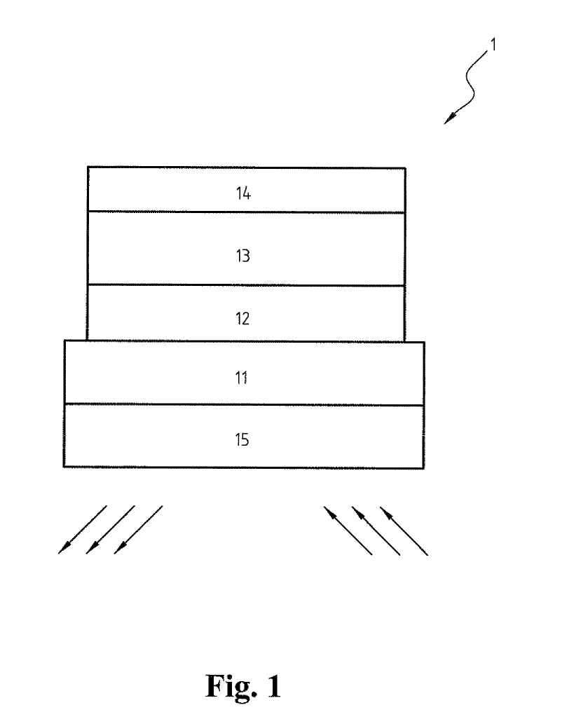

### DETAILED DESCRIPTION OF THE PRESENT INVENTION

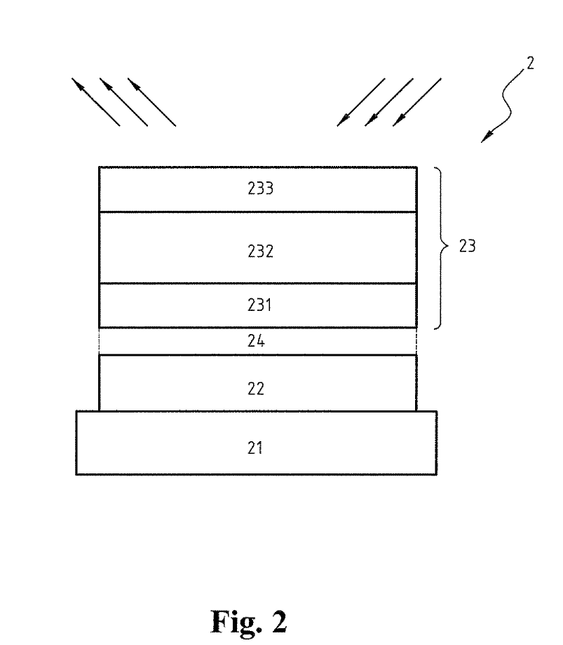

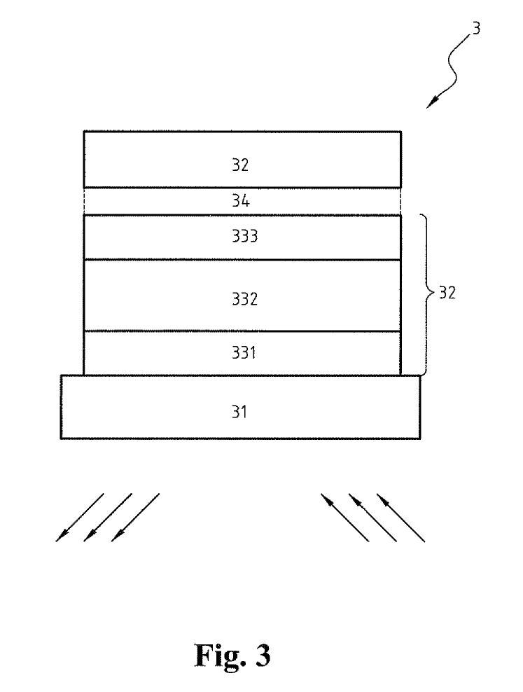

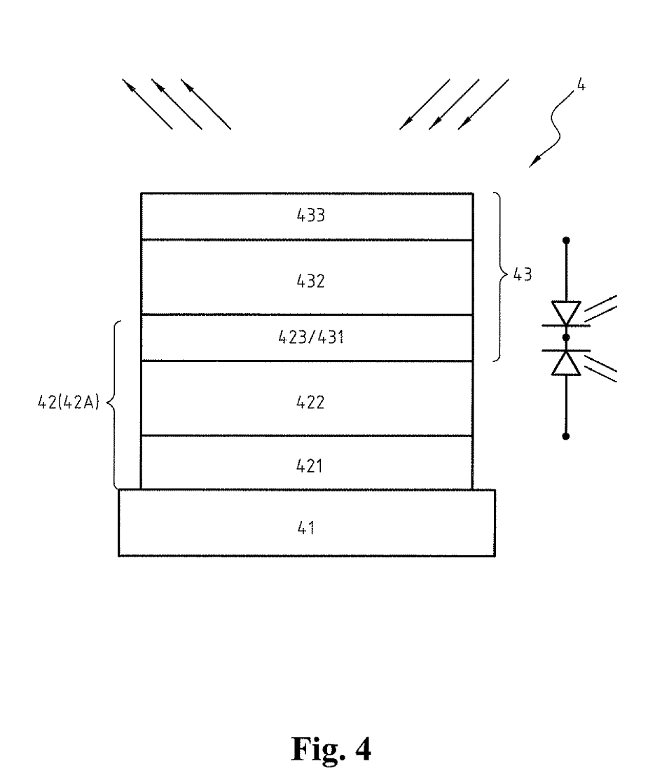

With reference to FIGS. 2˜4, 9, 11, 13 and 15, an organic light emitting diode (OLED) (2, 3, 4, 5, 6, 7, 8) display device with an energy-recycling feature and high contrast in accordance with the present invention may be top-emitting or bottom-emitting and comprises a substrate (21, 31, 41, 51, 61, 71, 81), a photovoltaic element (22, 32, 42, 52, 62, 72, 82), a translucent OLED element (23, 33, 43, 53, 63, 73, 83) and an optional insulation layer (24, 34, 64, 74, 84) and mounted against each other to form the OLED display device (2, 3, 4, 5, 6, 7, 8).

The substrate (21, 31, 41, 51, 61, 71, 81) may be semiconductor material, glass, metal, insulated material or a thin-film transistor circuit board (85) and has a top surface.

The photovoltaic element (22, 32, 42, 52, 62, 72, 82) may be mounted on the top surface of the substrate (21, 41, 71), converts light with wavelengths from 200 to 2000 nm striking the photovoltaic element (22, 32, 42, 52, 62, 72, 82) to electricity, has a top surface and a bottom surface, may be an organic solar cell (42A), an inorganic solar cell, a dye-sensitized solar cell, a tandem cell, an organic photovoltaic element (52A, 62A) or a non-crystalline silicon solar cell (72A), is organic material or inorganic material, comprises an optional anodic layer (421, 521, 621, 721, 821), a photovoltaic material layer (422, 522, 622, 722, 822) and an optional cathodic layer (423, 523, 623, 723, 823). The organic material is material such as pentacene, copperphthalocyanine (CuPc), 3,4,9,10-perylenetetra-carboxylic bis-benzimidazole (PTCBI) or C₆₀. The inorganic material is material such as α-Si:H, poly-Si, crystalline-Si, CdTe, CuInSe₂, compounds of group III and V elements or compounds of group II-VI elements.

The anodic layer (421, 521, 621, 721, 821) may be a 100 nm layer of molybdenum (Mo) and a 30 nm layer of indium tin oxide (ITO), a single layer of gold or a 120 nm layer of chromium (Cr).

The photovoltaic material layer (422, 522, 622, 722, 822) may be formed on the anodic layer (421, 521, 621, 721, 821) and may be an organic photovoltaic material layer (422, 522, 622, 722, 822). The organic photovoltaic material layer (422, 622) is a 30 nm layer of copper phthalocyanine (CuPc) and a 50 nm layer of 3,4,9,10-perylenetetra carboxylic bis-benzimidazole (PTCBI) sputtered on the anodic layer (421) by thermal evaporation, a 50 nm layer of PTCBI and a 30 nm layer of CuPc, a 15 nm layer of p-type doping amorphous silicon, a 350 nm layer of non-doping amorphous silicon and a 10 nm layer of n-type doping crystalline silicon or a 350 nm layer of amorphous silicon and a 10 nm membrane of p-type doping amorphous silicon.

The cathodic layer (423, 523, 623, 723, 823) is formed on the photovoltaic material layer (422, 522, 622, 722, 822) opposite to the anodic layer (421, 521, 621, 721, 821) and may be an 18 nm layer of silver (Ag) or a layer of ITO.

The OLED element (23, 33, 43, 53, 63, 73, 83) is vertical stacking to the photovoltaic element that may be mounted above the photovoltaic element (22, 42, 82) or the top surface of the substrate (31, 51, 61, 71) and comprises a lower electrode layer (231, 331, 431, 531, 631, 731, 831), an organic light-emitting material layer (232, 332, 432, 532, 632, 732, 832) and an upper electrode layer (233, 333, 433, 533, 633, 733, 833).

The lower electrode layer (231, 331, 431, 531, 631, 731, 831) may be mounted above the photovoltaic element (22, 42, 72, 82) or against the top surface of the substrate (31, 51, 61), may be translucent, may be common with the cathodic layer (423) of the photovoltaic element (42), may be a cathode or an anode, is a common cathode when common with the cathodic layer (423) of the photovoltaic element (42), may be a metal, a chemical compound or a mixture of metal and chemical compound and has a top surface. The metal is selected from the group of Au, Ag, Cu, Al, Cr, Mo, Ti, Ni, Pt, Ir, Pd, Mg, Ca, Ba, Li, Be, Sr and alloys of the foregoing metals. The compounds are selected from the group of ITO, IZO, SnO₂F (FTO), ZnO:Al, ZnO:Ga, ZnO:F and composition of foregoing chemical compounds.

The organic light-emitting material layer (232, 332, 432, 532, 632, 732, 832) is mounted on the top surface of the lower electrode layer (231 331, 431, 531, 631, 731, 831), receives electricity from the photovoltaic element (22, 32, 42, 52, 62, 72, 82), emits light when electricity from the photovoltaic element (22, 32, 42, 52, 62, 72, 82) is applied to the organic light-emitting material layer (232, 332, 432, 532, 632, 732, 832), has a top surface, may comprise a charge transport layer (CTL), a charge injection layer (CIL) or a CTL and a CIL and may be a 10 nm layer of Alq₃ doped with 20% cesium carbonate (Cs₂CO₃), a 50 nm layer Alq₃, a 20 nm layer of 4,4′-bis[N(1-naphthyl)-N-phenyl-amino]biphenyl (α-NPD) and a 30 nm layer of m-MTDATA doped with 2,3,5,6-tetrafluoro-7,7,8,8-tetracyanoquino-dimethane (Fa-TCNQ), a 30 nm layer m-MTDATA, a 30 nm layer of α-NPD and a 60 nm layer of Alq₃ or a 40 nm layer of α-NPD and a 60 nm layer of Alq₃.

The upper electrode layer (233, 333, 433, 533, 633, 733, 833) is formed on the organic light-emitting material layer (232, 332, 432, 532, 632, 732, 832), may be a 20 nm layer of silver (Ag) and a 30 nm layer of zinc selenide (ZnSe), a 0.5 nm layer of lithium fluoride (LiF), a 1 nm layer of aluminum and a 20 nm layer of silver, a 0.5 nm layer of LiF, a 1 nm layer of aluminum and a 120 nm layer of ITO or a 0.5 nm layer of LiF, a 1 nm layer of aluminum, a 20 nm layer of silver and a 30 nm layer of ZnSe, may be formed on the top surface of the organic light emitting material layer (232, 332, 632) and is translucent.

The TFT circuit board (85) may be an N-channel field-effect transistor, controls operation of the OLED element (83) and comprises a barrier layer (851), a TFT insulation layer (852), an active material layer (853), two insulation layers (854), a insulation layer (855), a source and drain electrode (856) and a gate electrode (857). The barrier layer (851) is mounted on the substrate (81). The drain (855) connects to the lower electrode layer (831) of the OLED element (83) to control operation of the OLED element (83).

The insulation layer (24, 34, 64, 74, 84) is translucent, may be mounted between the OLED element (23, 33, 63, 73) and the photovoltaic element (22, 32, 62, 72), may be silicon nitride (SiNₓ), may be a 330 nm layer, allows the OLED element (23, 33, 63, 73, 84) and the photovoltaic element (22, 32, 62, 72, 82) to operate independently, may comprise a lower insulation layer (84A) and an upper insulation layer (84B) and further isolates the TFT element (85) from the OLED element (83) and the photovoltaic element (82). The lower insulation layer (84A) is a 200 nm layer of silicon oxide formed between the TFT element (85) and the photovoltaic element (82). The upper insulation layer (84B) is a 330 nm layer of silicon oxide formed between the photovoltaic element (82) and the OLED element (83) and connects to the lower insulation layer (84A) to isolate the photovoltaic element (82).

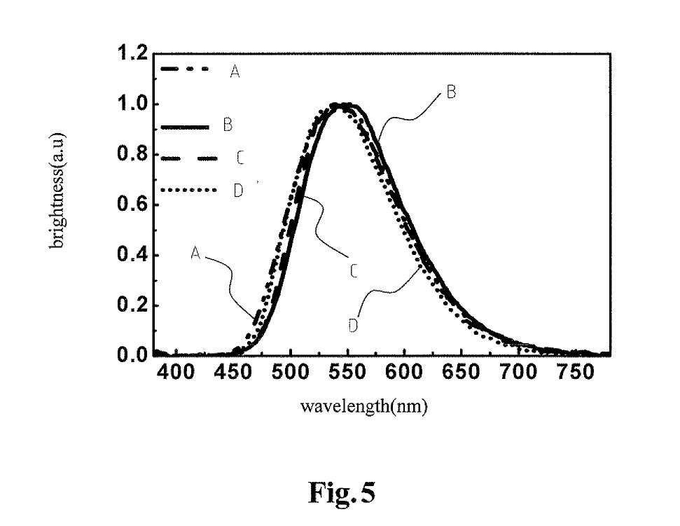

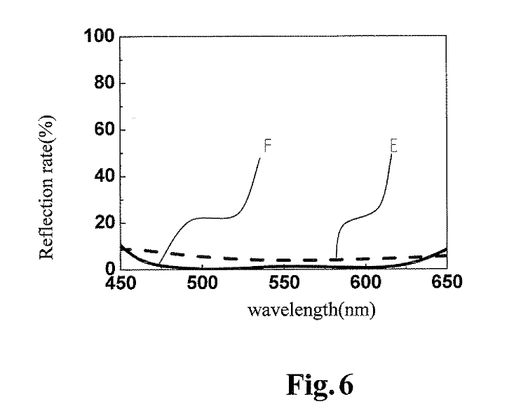

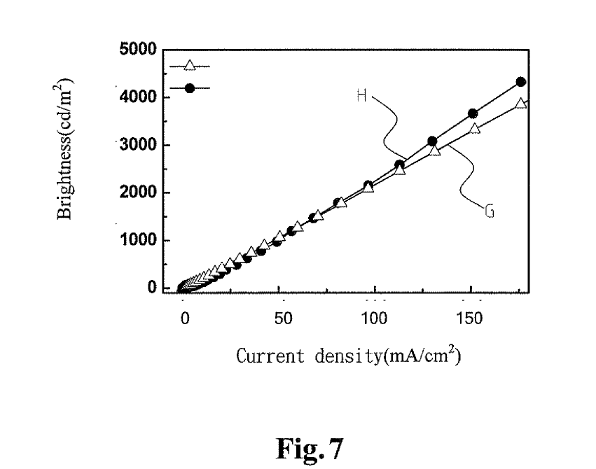

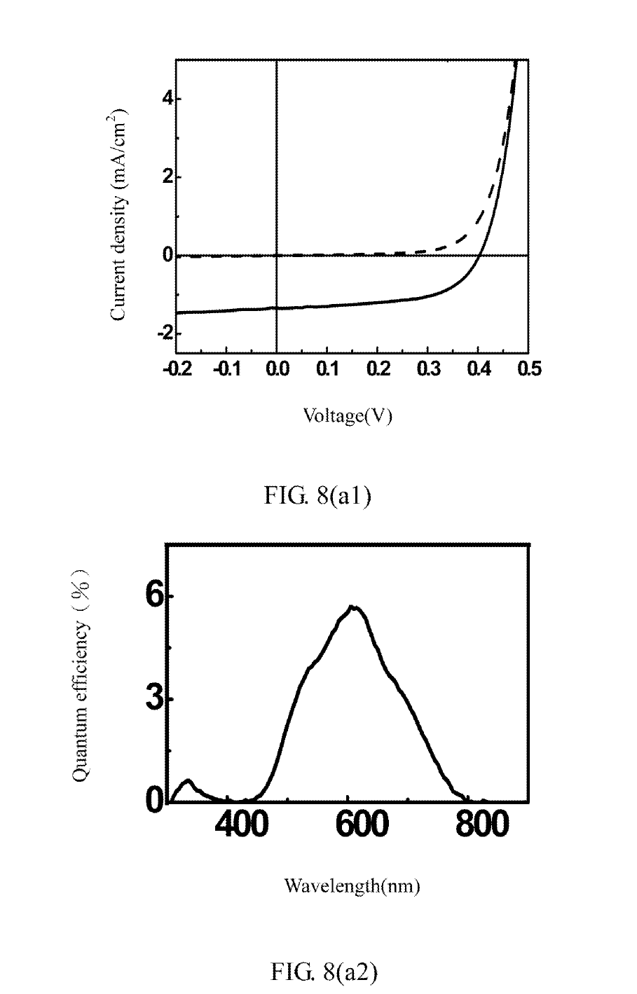

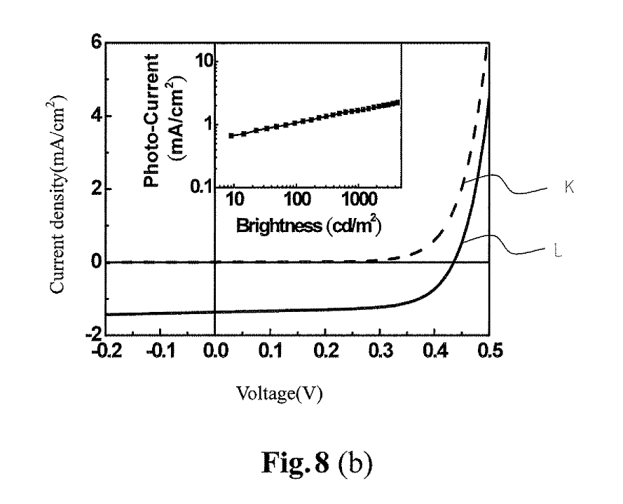

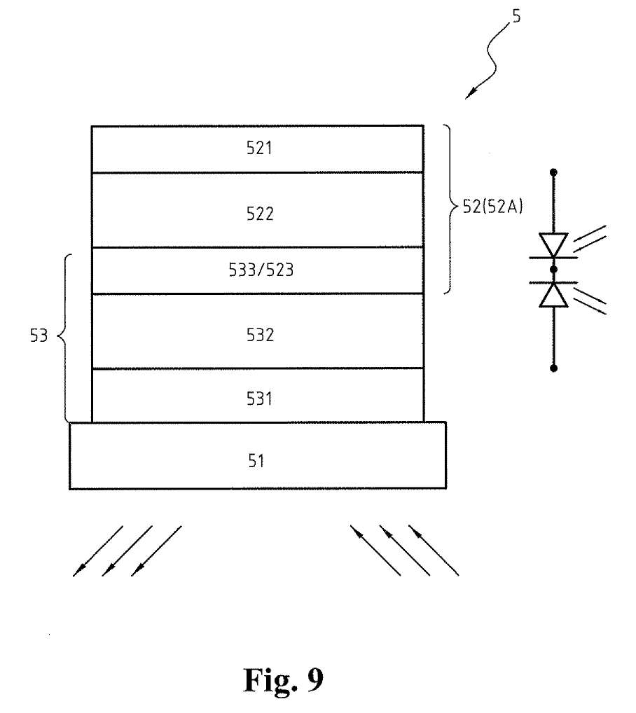

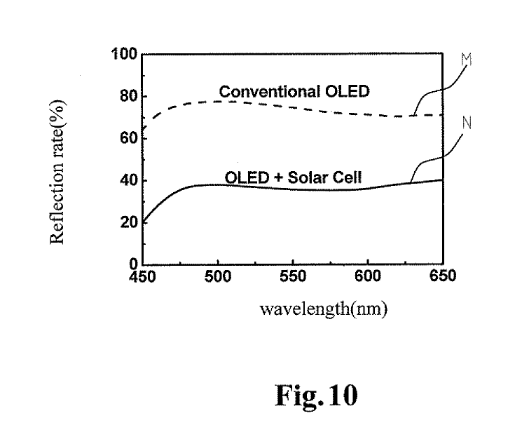

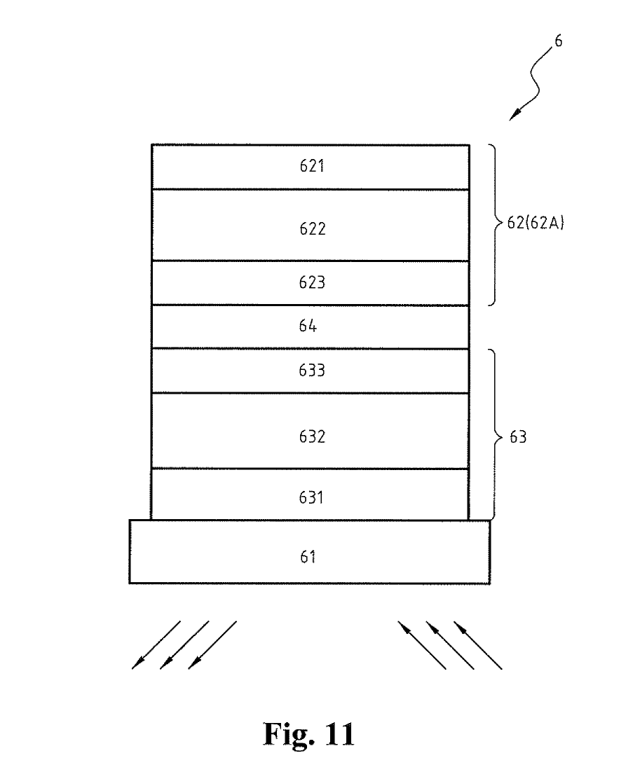

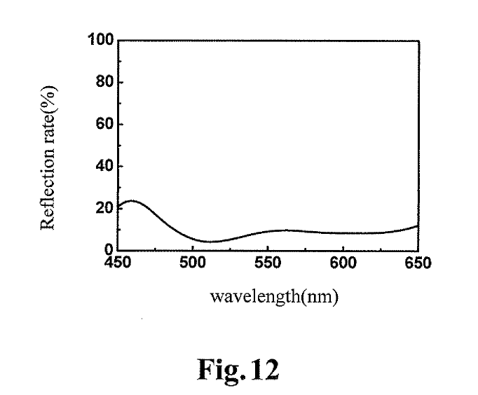

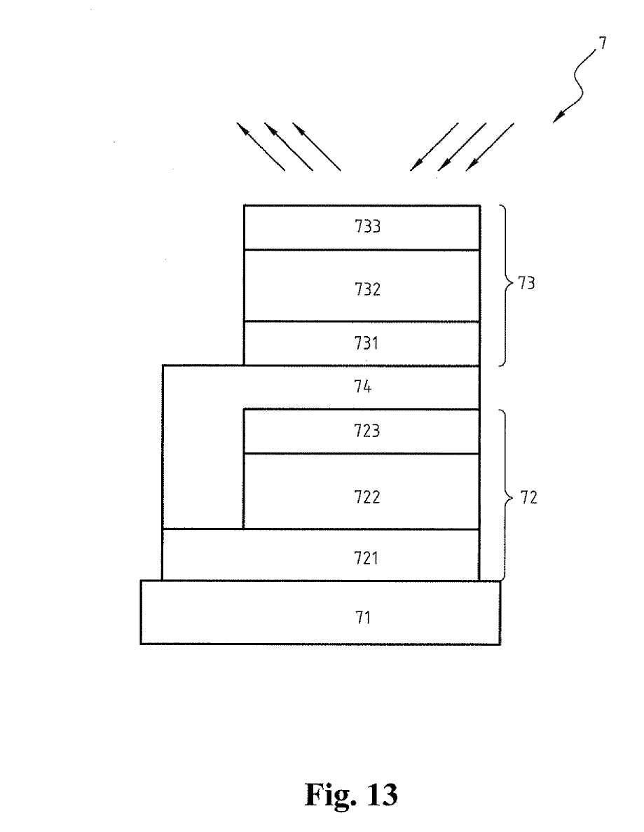

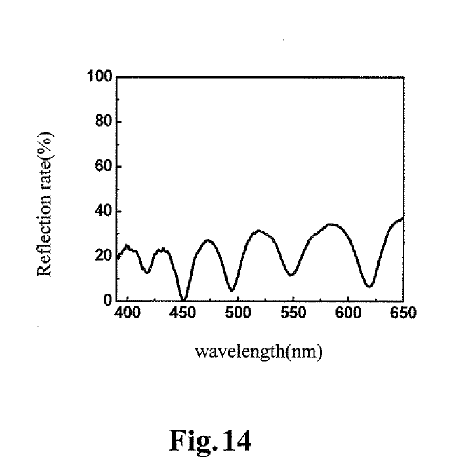

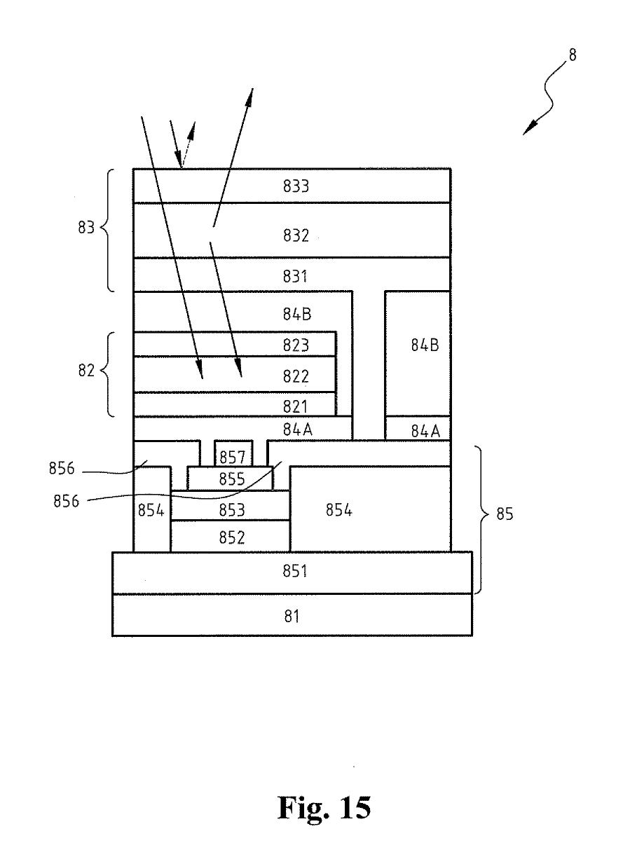

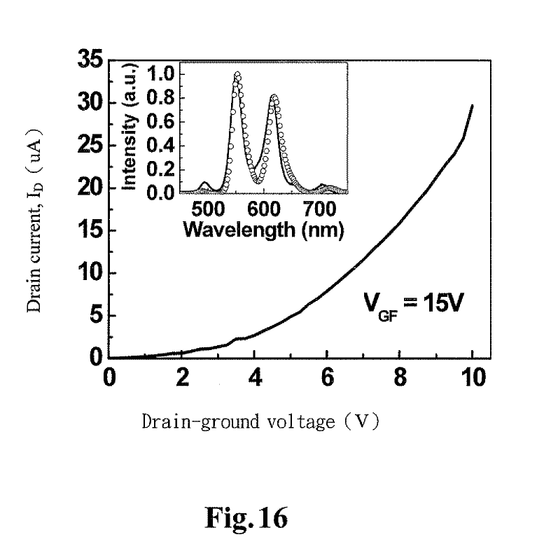

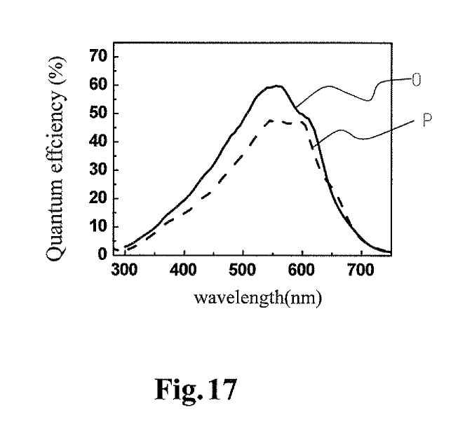

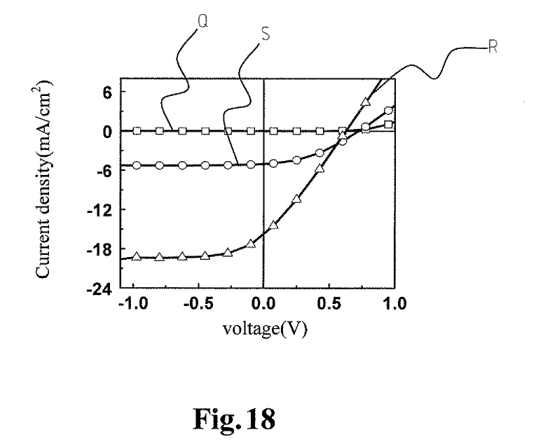

With reference to FIGS. 5, 6, 7, 8(a1), 8(a2), 8(b), 10, 12, 14 and 16˜18, the OLED in accordance with the present invention has numerous advantages and no significant disadvantages when compared to a conventional OLED. Specifically, luminescence spectra, brightness, reflection rate and lighting efficiency are essentially the same as or better than those of a conventional OLED.

For example, the reflection rate of a third and a sixth embodiment of an OLED in accordance with the present invention are respectively about 1.4% and 21% lower than a conventional OLED with a circular polarizer to reduce the reflection rate. Therefore, the OLED in accordance with the present invention will provide better contrast in a display device.

The lower insulation layer (84A) is a 200 nm layer of silicon oxide formed by PECVD between the TFT element (85) and the photovoltaic element (82).

The upper insulation layer (84B) is a 330 nm layer of silicon oxide formed by PECVD between the photovoltaic element (82) and the OLED element (83) and connects to the first insulation layer (84A) to isolate the photovoltaic element (82).

The invention is not intended to limit by the drawings or description. People skilled in the art will understand that various changes, modifications, and alterations in form and details may be made without departing from the spirit and scope of the invention.

What is claimed is:

1. A one-piece organic light emitting diode (OLED) display device with an energy-recycling feature and high contrast comprising:
a substrate having a top surface;
a photovoltaic element having a top surface and a bottom surface and comprising a photovoltaic material layer; and
a translucent OLED element being vertical stacking to the photovoltaic element and comprising
a lower electrode layer being translucent and having a top surface;
a translucent organic light-emitting material layer being mounted on the top surface of the lower electrode layer, and having a top surface; and
an upper electrode layer being translucent and formed on the organic light-emitting material layer.

2. The OLED display device as claimed in claim 1, wherein the OLED display device is top-emitting and the photovoltaic element is mounted between the substrate and the OLED element.

3. The OLED display device as claimed in claim 1, wherein the OLED display device is bottom-emitting and the OLED element is mounted between the substrate and the photovoltaic element.

4. The OLED display device as claimed in claim 1 further comprising an insulation layer being translucent and mounted between the OLED element and the photovoltaic element.

5. The OLED display device as claimed in claim 1, wherein the substrate is semiconductor material, glass, metal, insulated material or a thin-film transistor circuit board.

6. The OLED display device as claimed in claim 1, wherein the photovoltaic element is mounted on the top surface of the substrate.

7. The OLED display device as claimed in claim 1, wherein the photovoltaic element converts light with wavelengths from 200 to 2000 nm to electricity.

8. The OLED display device as claimed in claim 1, wherein the photovoltaic element is an inorganic solar cell, an organic photovoltaic element or a non-crystalline silicon solar cell.

9. The OLED display device as claimed in claim 1, wherein the photovoltaic element is further comprises:
an anodic layer; and
a cathodic layer being formed on the photovoltaic material layer opposite to the anodic layer.

10. The OLED display device as claimed in claim 1, wherein the photovoltaic material layer is an organic material or an inorganic material.

11. The OLED display device as claimed in claim 1, wherein the organic light-emitting layer with emission wavelengths from 400 to 800 nm.

12. The OLED display device as claimed in claim 1, wherein the organic light-emitting layer further comprising a charge transport layer (CTL) and/or a charge injection layer (CIL).

13. The OLED display device as claimed in claim 9, wherein
the photovoltaic material layer is formed on the anodic layer; and
the lower electrode layer is mounted above the photovoltaic element and is a cathode.

14. The OLED display device as claimed in claim 9, wherein the anodic layer, the cathodic layer, the lower electrode layer and the upper electrode is a metal, a chemical compound or a mixture of a metal and a chemical compound.

15. The OLED display device as claimed in claim 9, wherein
the anodic layer is a layer of molybdenum (Mo) and a layer of indium tin oxide (ITO);
the photovoltaic material layer is formed on the anodic layer and is an organic photovoltaic material layer.

16. The OLED display device as claimed in claim 9, wherein
the anodic layer is a single layer of gold;
the photovoltaic material layer is formed on the anodic layer and is an organic photovoltaic material layer being a layer of PTCBI and a layer of CuPc.

17. The OLED display device as claimed in claim 9, wherein
the anodic layer is a layer of molybdenum (Mo) and a layer of indium tin oxide (ITO); the photovoltaic material layer is formed on the anodic layer and is an organic photovoltaic material layer being a layer of PTCBI and a layer of CuPc.

18. The OLED display device as claimed in claim 9, wherein
the anodic layer is a single layer of gold;
the photovoltaic material layer is formed on the anodic layer and is an organic photovoltaic material layer.

19. The OLED display device as claimed in claim 9, wherein
the anodic layer is a layer of chromium (Cr); the photovoltaic material layer is formed on the anodic layer and is an organic photovoltaic material layer being a layer of amorphous silicon.

20. The OLED display device as claimed as claimed in claim 9, wherein the anodic layer is a layer of chromium (Cr).

21. The OLED display device as claimed in claim 10, wherein the organic material is selected from the group of pentacene, copperphthalocyanine (CuPc), 3,4,9,10-perylenetetracarboxylic bis-benzimidazole (PTCBI) or C₆₀.

22. The OLED display device as claimed in claim 4, wherein the insulation layer is an inorganic insulated material or an organic insulated material.

23. The OLED display device as claimed in claim 14, wherein the metal is selected from the group of Au, Ag, Cu, Al, Cr, Mo, Ti, Ni, Pt, Ir, Pd, Mg, Ca, Ba, Li, Be, Sr and alloys of the foregoing metals.

24. The OLED display device as claimed in claim 14, wherein the compounds are selected from the group of ITO, IZO, SnO₂F (FTO), ZnO:Al, ZnO:Ga, ZnO:F and composition of foregoing chemical compounds

25. The OLED display device as claimed as claimed in claim 22, wherein the organic insulated material is selected form a group comprising parylene and polyimide(PI).

26. The OLED display device as claimed as claimed in claim 22, wherein the inorganic insulated material is selected from a group comprising Silicon oxide, HfO₂, Al₂O₃ and Si₃N₄.
